(19) United States
(12) Patent Application Publication
(10) Pub. No.: US 2012/0251023 A1
(43) Pub. Date: Oct. 4, 2012

(54) METHOD FOR PRODUCING A PLAIN BEARING ELEMENT

(75) Inventor: Walter Gaertner, Gmunden (AT)

(73) Assignee: MIBA GLEITLAGER GMBH, Laakirchen (AT)

(21) Appl. No.: 13/508,096

(22) PCT Filed: Nov. 5, 2010
(86) PCT No.: PCT/AT10/00419

§ 371 Date: Jun. 13, 2012

(30) Foreign Application Priority Data
Nov. 5, 2009 (AT) A 1749/2009

(51) Int. Cl. C23C 14/34; F16C 33/14; F16C 33/06; C23C 14/14

(52) U.S. Cl. 384/276; 204/192.12; 204/192.15

(57) ABSTRACT

The invention relates to a method for producing a plain bearing element (1) by means of coating a surface (5) of a substrate with a tribologically effective sliding layer (6) by means of cathode sputtering in a gas atmosphere and using at least one metal target (16), with a substrate having a cylindrical cavity (3) being used, and the target (16) being arranged at least partially in the cavity (3) and furthermore the discharge for sputtering the target (16) is supported or maintained by means of a third electrode (26).

The invention relates to a method for producing a plain bearing element by means of coating a surface of a substrate with a tribologically effective sliding layer by means of cathode sputtering in a gas atmosphere using at least one metallic target as well as a metallic plain bearing element with a bearing element body which has a support element and a cylindrical cavity having an interior surface and an inner diameter, with a metallic sliding layer being disposed on the interior surface of the bearing element body.

The separation of sliding layers on substrates for plain bearings by cathode sputtering is already known from prior art. Compared with other methods of production of bearing elements, the cathode sputtering is relatively expensive, on the one hand due to equipment needed, on the other hand due to the long cycle times. Therefore, cathode sputtering has only been used for the production of sliding layers with a high-load bearing capacity. Usually, with cathodes sputtering, the substrate is connected as anode and a target is connected as cathode. In the chamber, where the coating takes place, a residual gas is usually present. A voltage is applied between the anode and the cathode in order to accelerate the electrons towards the anode. This being the case, they collide with the gas particles and ionize the latter. These positively charged ionized gas particles are then accelerated towards the cathode and knock atoms out of the cathode, i.e. the target. In addition to neutral atoms of the target, emission electrons are released, which ionize further electrons. Between the two electrodes, thus, a steady state plasma results. The knocked out atoms of the target evenly spread in the entire chamber and therefore produce a layer on the substrate.

This being the case it is disadvantageous that due to the high pressure of the residual gas, a higher dispersion of the neutral atoms knocked out of the target is present, resulting in a deposited layer on the substrate which has a relatively high porosity.

In order to avoid this disadvantage, it was described in prior art, to subordinate an additional magnetic field to the electric field, with the result that die electrons in the field have a higher capacity to ionize and therefore the pressure of the residual gas can be further reduced. Due to the necessary magnetron, the space requirements for this kind of cathode sputtering increases, so that this method can only be applied from a minimum diameter for bearing elements having cylindrical cavities in which a sliding layer is to be arranged.

The underlying objective of the invention is therefore to propose highly stressable cylindrical bearing elements having the smallest possible inner diameter.

This objective of the invention is achieved by the method mentioned at the beginning, where a substrate is used, which has a cylindrical cavity and the target at least partially being arranged in the cavity and furthermore the discharge for the sputtering of the target is supported or maintained by means of a third electrode, as well as independently thereof by the metallic plain bearing element, which has an inner diameter of the bearing element body of at most 70 mm and the sliding layer of which is produced by cathode sputtering.

By the arrangement of the third electrode, a “decoupling” of the plasma generation from the actual sputtering of the target as well as the subsequent deposition of the atoms of the target for the formation of the layer on the substrate is achieved. It is therefore possible to dispose the target within this cavity and the cavity can have a very small diameter of at most 70 mm. Additionally, due to the third electrode, also a higher quantity of electrons is generated, with the result that higher coating rates and/or lower process pressures can be achieved. Consequently, using the method, very thick layers and thus very highly stressable layers can be obtained as sliding layers. Due to the arrangement of the target in the cavity and the short distance between the surface of the substrate and the surface of the target, the sputtered atoms undergo a slight deflection on their track in direction towards the surface of the substrate, so that no additional measures for separation are required, as for example the above described magnetic field of the prior art method. Since the target can be disposed within the cavity, the further advantage can be achieved that the coating chamber per se can be designed less complex in terms of equipment, because it is possible for the substrate itself to be used as a part of the coating chamber.

Preferably, a glowing cathode is used as a third electrode. Thus, the advantage is achieved, that the quantity of the emitted electron can be controlled very well, with the result that the growth of the layers can be influenced correspondingly positively. Even though hot cathodes can have the disadvantage of being sensitive to reactive gases, the advantages are predominant.

As a target particularly an alloy is used, which starts melting at a temperature higher than 200° C. or melts at this temperature. On the one hand, this is of advantage in terms of the sputtering behavior of the target itself, on the other hand, thus the advantage is achieved that soft, low-melting tribological coatings can be produced. These coatings particularly have a positive behavior in terms of the ability to embed foreign particles.

The target can also be made of an alloy having a first melting point of 250° C. or 300° C.

The target is particularly formed from an alloy containing as a main alloy element an element selected from a group comprising Al, Cu, Ag, Sn, Pb, Bi, Sb, Au, Mg, Zn. Particularly such alloys are sufficiently described in prior art and have sufficiently proved themselves in practice for producing a plain bearing element.

According to a variant of embodiment it is provided to use a target having a maximum diameter selected from a range from 5 mm to 55 mm. Thus, sliding layers can be produced which do not require further processing, with the result that the method can be performed correspondingly efficient. The diameter of a target can for example be selected from a range from 10 mm to 40 mm or from 15 mm to 35 mm.

It is in particular of advantage if the minimum distance between the surface of the substrate and the surface of the target is at least 5 mm, in particular at least 7.5 mm, preferably at least 10 mm. At a distance smaller than 5 mm, it could have been observed that no stable plasma can be ignited.

It is also of advantage if, before the production of the tribologically effective layer on the surface of the substrate, this surface is cleaned be inverse cathode sputtering by using an inert gas, with the result that the entire coating procedure can be performed in the same facility, in particular making it possible again for the advantages of using the substrate as a part of the coating facility to be realized.

During the cleaning of the surface, a voltage of between −300 V and −1400 V can be applied to the substrate, in order to enhance the cleaning effect.

It is in this case also possible that the voltage applied to the substrate is between −400 V and −1300 V or between −450 V and −1000 V during the cleaning of the surface of the substrate.

According to a variant of embodiment it is provided that during the coating a bias voltage is applied to the substrate, which is selected from a range having a lower limit of −200 V and an upper limit of −10 V. Thus, the advantage is achieved that the substrate is bombarded with positive ions of the residual gas in the coating chamber so that impurities can be removed.

This being the case, this bias voltage can also be embodied from a range having a lower limit of −150 V and an upper limit of −50 V or a range having a lower limit of −100 V and an upper limit of −75 V.

It is also of advantage if the temperature of the substrate is controlled and/or regulated during the coating, in particular in terms of using alloys as target, the first melting point of which is 200° C. and therefore avoiding a grain growth or the formation of undesired alloy phases.

According to a variant of embodiment of the plain bearing element it is provided for the bearing element body to have a length in axial direction which is larger than its inner diameter.

Using a method according to the invention it is particularly possible to produce plain bearing elements the bearing element bodies of which are embodied without seams, i.e. no weld is present at theses plain bearing elements for example, and which have a correspondingly small diameter of not more than 70 mm, so that consequently no stresses, which can appear with this weld, are present with the plain bearing element according to the invention. Additionally, the processing effort for the production of the finished plain bearing element can be reduced correspondingly.

The inner diameter can particularly be not more than 60 mm or not more than 50 mm or not more than 30 mm. The lower limit of the inner diameter results in each case from the diameter of the target used plus the distance between the surface of the substrate and the surface of the target, in particular the minimum distance as described above.

It is finally also of advantage if the plain bearing element produced using the method has a sliding layer, the structure of which is free of textures in axial direction, i.e. plain bearing elements which have improved running features can be produced.

For a better understanding, the invention will be explained in more detail below according to the figures shown in the drawings.

These show:

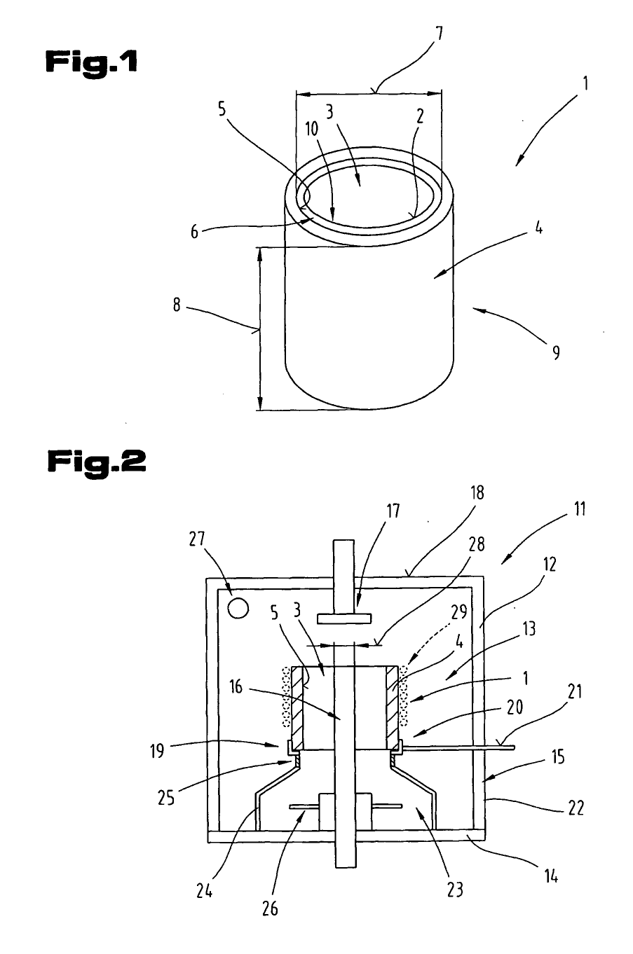

FIG. 1 a plain bearing element according to the invention in perspective view;

FIG. 2 a variant of embodiment of an apparatus for performing the method according to the invention.

It must first be stated that in the various embodiments described, identical parts have been marked with the same reference identifiers and the same parts descriptions. It is therefore possible to transfer the disclosures contained in the overall description to the identical parts with the same reference identifiers or the same parts descriptions. The selected positioning terms are used in the description, such as top, bottom, side etc., which refer directly to the described and the depicted figures and which can be correspondingly transferred to the new position in the event of a change in position.

All the figures relating to ranges of values in the description should be construed as meaning that they include any and all part-ranges, in which case, for example, the range of 1 to 10 should be understood as including all part-ranges starting from the lower limit of 1 to the upper limit of 10, i.e. all part-ranges starting with a lower limit of 1 or more and ending with an upper limit of 10 or less, e.g. 1 to 1.7, or 3.2 to 8.1 or 5.5 to 10.

FIG. 1 shows an embodiment of a plain bearing element 1 according to the invention. This has the form of a so-called plain bearing bushing, i.e. it is formed from a non-eccentric, rotationally symmetric body having a closed interior surface 2. In other words, the plain bearing element 1 according to FIG. 1 is embodied to be tubular.

Within the scope of the invention, also other plain bearing elements 1 can be produced using the method according to the invention, which have a cylindrical cavity 3 as shown in FIG. 1. The plain bearing element 1 can be a connecting rod, for example, the connecting rod eye of which is provided with a coating according to the invention.

In the simplest exemplary embodiment according to FIG. 1, the plain bearing element 1 comprises a support element 4 with an interior surface 5, with a tribologically effective sliding layer 6 being disposed at the interior surface 5 and being connected to the support element 4. If necessary, a bonding layer and/or a diffusion barrier layer can be arranged between the sliding layer 6 and the support element 4. Furthermore, it is possible for a bearing metal coat to be disposed between the support element 4 and the sliding layer 6.

Due to the fact that this layer structure of plain bearing elements 1 is already known from prior art, it is with this respect referred to the relevant prior art in order to avoid unnecessary repetitions.

The support element 4 is usually formed from a steel or a material having comparable characteristics in terms of structural strength, because the mechanical strength of the plain bearing element 1 is essentially provided by this support element 1. Examples for other materials are different copper alloys like brass or bronze, or usual casting materials made of iron base alloys.

The sliding layer 6 itself is preferably made of a base alloy having an element selected from an element group comprising Al, Cu, Ag, Sn, Bi, Sb as a main alloy element. This being the case, the base element represents the major part in terms of quantity compared to the other alloy elements.

Examples for alloys of this kind are:
Al-base alloys: Al—Sn alloys, Al—Sn—Cu alloys, Al—Sn—Ni—Mn alloys, Al—Sn—Si alloys, Al—Sn—Si—Cu alloys, AlBi15Mo2, AlBi11Cu0, 5Ni0, 5, AlBi25Cu, AlSn25Si7, 5, AlSn20, AlSn20Cu, AlSn20Sb10;
Cu-base alloys: CuBi40, CuBi20, CuAg20, CuSn8-10;
Ag-base alloys: AgSn10-40, AgCuSn, AgSn20, AgBi15, AgCu20;
Sn-base alloys: SnCu10, SnAg20, SnSb20Cu5;
Bi-base alloys: BiCu0, 1-10Sn0, 5-10, BiAg20, BiCu20;

Except from impurities resulting from the manufacturing process, lead-free alloys are preferably used.

The support element 4 has an inner diameter 7 which is not larger than 70 mm, in particular not larger than 60 mm, preferably not larger than 50 mm or not larger than 40 mm.

Furthermore, a proportion of this inner diameter 7 to a length 8 of a bearing element body 9 comprising the support element 4 and the sliding layer 6 is preferably smaller than 1. In other words, the length 8 of the plain bearing element 1 is larger than the inner diameter 7.

Within the scope of the invention, it is however of course also possible to coat support elements 4, the inner diameter 7 of which is larger than their length 8.

The support element 4 is preferably embodied seamless, it can thus be formed from a tube, for example. However, within the scope of the invention it is possible for the support element 4 to be produced by metal forming and to weld together the two face surfaces of the jacket of the support element 4 facing each other, which is however connected to a certain rework in order to achieve a surface as even as possible at least at the interior surface 5 of the support element 4. Furthermore, such an embodiment is not preferred within the scope of the invention, because the properties of the material, e.g. the thermal conductivity, correspondingly change at this transition to the welded joint, which can probably result in negative influences in terms of the plain bearing element 1 in use.

The sliding layer 6 has a coat thickness of at least 10 μm. For example, a coat thickness from a range having a lower limit of 10 μm and an upper limit of 250 μm can be selected. The coat thickness can in particular be selected from a range having a lower limit of 80 μm and an upper limit of 150 μm.

This even coat thickness has in particular advantages in terms of the running features of the plain bearing element 1 and according to the invention the advantage is achieved to obtain this even coat thickness already during the production process itself without requiring reworking, for example machining. This being the case, also the advantage is achieved that in the event that a further layer, e.g. a running-in layer made of an anti-friction varnish, is applied to this sliding layer 6, it also provides a coating thickness as even as possible.

As running-in layer an anti-friction varnish can e.g. be used which forms a polymer layer of a polyamidimid resin, molybdenum disulfide and graphite with the proportion of the polyamidimid resin being selected from a range having a lower limit of 23% by weight and an upper limit of 36% by weight, the proportion of MoS₂ is selected from a range having a lower limit of 40% by weight and an upper limit of 49% by weight and the proportion of graphite is selected from a range having a lower limit of 23% by weight and an upper limit of 29% by weight. Particularly preferred is a polyamidimid resin, at least the main chain of the molecule structure of which has a completely conjugated bond system. In this case, the proportion of the polyamidimid resin can be between 20% by weight and 50% by weight, in particular between 30% by weight and 40% by weight. In this case, also other solid lubricants, such as SnS, SnS₂, WS₂, for example, additionally or alternatively to the previously mentioned solid lubricants, with the latter forming the remaining proportion up to the 100% by weight.

There is furthermore the possibility to apply also a metallic running-in layer, for example of Sn, after applying the sliding layer 6, as it has been described in the prior art.

A plain bearing element 1 has the advantage that the sliding layer 6, due to the production method, has no or no distinctive structural texture, i.e. no distinctive orientation of the crystallites in axial direction of the plain bearing element 1.

Despite the small inner diameter 7 of the support element 4, the sliding layer 6 is made according to the method of cathode sputtering, with the result that the sliding layer 6 is seamless, i.e. an uninterrupted sliding layer 6 across the entire circumference 10 and the entire length 8 is formed.

For producing this plain bearing element 1, FIG. 2 shows a possible variant of embodiment of an apparatus 11.

This apparatus 11 comprises a housing 12, which can be closed vacuum-tightly and also all required feedthroughs through the housing 12 are embodied correspondingly vacuum-tightly.

The housing 12 defines a treatment chamber 13 where the support element 4 for depositing the sliding layer 6 (FIG. 1) is arranged in. In order to insert the support element 4 into this treatment chamber 13 it is on the one hand possible for a corresponding lock to be present at the housing 12, on the other hand it is also possible for the housing 12 to be embodied in a spilt way, for example having a bottom 14 and a hood 15 which can be detached therefrom, as it is shown in FIG. 2. The connection of these two parts of the housing can for example be performed by means of a screw connection etc. but it has to be ensured that a vacuum-tight connection is created.

Aside from the support element 4, an in particular rod-shaped or cylindrical target 16 is such disposed that it at least is partially projects within the support element 4, i.e. into its cavity 3. At least partially means that it is within the scope of the invention possible for the coating, i.e. the sliding layer 6, not to be applied across the entire length 8 (FIG. 1) of the plain bearing element 1, but also to a portion of the latter. It is however preferred to provide the entire surface 5 of the support element 4 with a sliding layer 6, as shown in FIG. 1. For this purpose, the target 16 projects at least approximately through the entire cavity 3 of the support element 4.

With this variant of embodiment of the apparatus 11, the target 16 is lead through the bottom 14 in order to provide electrical contact. Within the scope of the invention it is of course possible for the target 16 to be embodied shorter and led outwardly via an electrical contact. The target 16 can for example have a length that at least approximately corresponds to the length 8 of the plain bearing element 1 (FIG. 1).

In axial direction of the target 16 and of the support element 4 and opposite the target 16, a second electrode 17 is disposed providing an outward connection through a cover surface 18 of the apparatus 11 in order to make electrical contact. This being the case, the electrode 17 is formed disk-shaped and has a preferred exterior diameter that at least approximately corresponds to the inner diameter 7 of the support element 4.

Although this is the preferred embodiment of the further electrode 17, it is within the scope of the invention possible for the electrode 17 to have a smaller expansion in terms of area than the cross-sectional area of the support element 4, i.e. of the cavity 3.

The support element 4 is arranged within the treatment chamber 13 on a holding device 19. With the variant of embodiment shown, the support element 4 with its face surfaces stands on the holding device 19, and the holding device 19 can provide an circumferential bar 20 or a lateral wall which is embodied correspondingly higher and which partially surrounds the exterior of support element 4. For further fixation of the support element 4, corresponding fixing devices can be disposed at the holding device 19, for example corresponding clamping devices.

In order to establish electrical contact, the holding device 19 can be connected to a source of energy via a contacting 21 as well, which is in the event of the variant of embodiment according to FIG. 2, lead through a lateral wall 22 of the housing 12.

Underneath the holding device 19, a funnel-shaped tapered cavity 23 is disposed, which is limited at least approximately by a cylindrical lateral wall 24 in the direction towards the bottom 14 of the housing 12. Between the lateral wall 24, i.e. the funnel-shaped end of this lateral wall 24, and the holding device 19, an insulating element 25 is disposed, which is used to achieve an electrical insulation of these two components of the apparatus 11.

In this cavity 23, a third electrode 26 is arranged, which preferably embodied as a glowing cathode. This third electrode 26 can for example be formed from tungsten, tantalum or LaB₆. This electrode 26 is of course arranged electrically insulated with respect to the target 16.

Furthermore, a recess 27 is provided in the housing 12, via which the treatment chamber 13 can be evacuated or flushed.

During the coating process, electrons are emitted from the third electrode 26 and accelerated in the direction of the second electrode 17, which is connected as an anode. Since a residual gas, e.g. a noble gas, particularly Argon, is present in the treatment chamber 13, these electrons, on their way in the direction of the anode, i.e. the second electrode 17, meet noble gas atoms and ionize the latter. The positively charged, ionized noble gas atoms are then accelerated in the direction of the cathode, i.e. the target 16, and strike out atoms of the target material, with the result that they deposit on the interior surface 5 of the support element 4 and therefore realize the layer structure for producing the sliding layer 6.

The support element 4 can be at earth potential. For the above mentioned reason, it is furthermore possible to apply a bias voltage, which is selected from a range having a lower limit of −200 V and an upper limit of −10 V, at the support element 4.

A voltage, which is selected from a range having a lower limit of 30 V and an upper limit of 150 V, e.g. 60 V, can be present on the second electrode 17, i.e. the anode.

The target 16 itself can have a voltage selected from a range having a lower limit of −1500 V and an upper range of −200 V or which is selected from a range having a lower limit of −1000 V and an upper limit of −500 V.

On the glowing cathode, i.e. the electrode 26, a voltage can be present, which is selected from a range having a lower limit of 10 V and an upper limit of 50 V or a current which is selected from a range having a lower limit of 75 A and an upper limit of 200 A. A voltage of 15 V and a current of 150 A can for example be used.

The current density being present on the target can be between 5 mA/cm² and 15 mA/cm², for example 9 mA/cm².

The glowing cathode can have a temperature between 1700 K and 2700 K, for example being heated to 2300 K, depending on the materials used therefor.

The coating is effected using direct current.

The material of the target is preferably made of the alloy which is used for the coating of the sliding layer 6. The target 16 can for example be produced through powder metallurgy. In principle, the production of such a target 16 is already described in the prior art and is known.

The target 16 is particularly made of an alloy having a first melting point of 200° C., as described above.

It is furthermore of advantage if a maximum diameter 28 of the target 16 has a value of at most 55 mm.

Naturally, the alloy for the production of the target 16 can also have so-called hard phases or hard phase additives, the hard phase can for example be or can be made of at least one element from a group comprising Cr, Fe, Co, Cu, Mn, Ni, Mo, Mg, Nb, Pt, Sc, Ag, Si, V, W, Zr and/or aluminides, carbides, silicides, nitrides, borides of the elements in order to produce hard phases also in the sliding layer 6, which hard phases provide the sliding layer 6 with a higher abrasion resistance, with the sliding layer 6—as known per se—having also proportions of soft phases, e.g. Sn, Bi, Sb, Pb, providing a better embeddability for foreign particles from abrasion during the use of the plain bearing element 1.

In a variant thereto, there is the possibility for the plain bearing element 1 to be turned around the target 16 during the coating, for which purpose, for example the holding device 19 can be connected to a corresponding turning device, i.e. mounted in a rotatable way. Further it is possible too that the target is mounted rotatable.

In a simplification of this apparatus 11 for cathode sputtering, there is the possibility for the housing 12 to be omitted and, expressed in a simplified way, the housing 12 is formed from the support element 4, which is vacuum-tightly connected to the holding device 19, and the second electrode 17, which can in this case form a kind of cover, which is electrically insulated and also vacuum-tightly resting against the region of the end face of the support element 4 opposite the holding device 19 and connected to the support element 4. In this case, e.g. the cavity 23, wherein a glowing cathode, i.e. the third cathode 26, is disposed and which is embodied underneath the support element 4, can have the recess 27 via which the evacuation of this simplified apparatus 11 or the flushing or insertion of gas into the treatment chamber is made.

With both described variants of embodiments of the apparatus 11, also a cleaning of the surface 5 of the support element 4 prior to the actual treatment, i.e. prior to the deposition of the sliding layer 6, by means of invers cathode sputtering by using an inert gas like argon is possible. For this purpose, a voltage of between −200V and −10V can be applied to the substrate, i.e. the support element 4, with the result that the positive argon-ions produced by the glowing cathode via the electrons are accelerated in the direction towards the surface of the substrate, i.e. the surface 5 of the support element 4, where they strike out impurities.

Aside from the cleaning by inverse cathode sputtering, it is naturally possible for the substrate to be coated to be (pre-)cleaned by means of the usual cleaning procedures, for example solvents, etc.

In a further variant of the apparatus 11, it is possible for the temperature of the support element 4, i.e. of the substrate, to be open loop controlled and/or closed loop controlled during the coating, for which purpose for example cooling- and/or heating elements 29 (in FIG. 2 shown in dashed lines), that can be flown through by a cooling liquid, e.g. water, can be disposed in the treatment chamber 13 distributed on the outer surface of supporting element 4. These cooling- and/or heating elements 29 can in this case also be disposed in a corresponding cooling jacket.

Within the scope of the invention, there is furthermore the possibility to deposit sliding layers 6, which can have a concentration gradient for at least one alloying element considered in terms of their coat thickness. It is for example possible for a soft phase element to have an increasing concentration, starting at the surface adjacent to the support element 4 in the direction towards the sliding layer 6, whereas the proportion of the hard phase can increase reversely. In order to achieve this, the target 16 can for example have a layered structure, i.e. that the concentration in terms of hard phase elements is higher in the outer regions than in the regions closer to the core of the target 16.

Only some selected exemplary embodiments of the invention of the tests carried out within the course of the invention are given in the following:

### 1. Exemplary Embodiment

A cylindrical tube or a bushing of steel having a length of 5 cm and an inner diameter of 3 cm was provided as support element 4. Then, this tube was inserted into the treatment chamber 3 of a test apparatus, which treatment chamber was then evacuated. If necessary, the treatment chamber can be flushed with argon several times and intermediately evacuated after the tube had been inserted.

After the insertion, the surface was cleaned by inverse cathode sputtering using Ar as process gas. This being the case, the following parameters were set:
Voltage: 450 V
Duration: 10 minutes

An alloy target of CuSn8 was used as target 16 for the deposition of the sliding layer 6. The following parameters were set:
Pressure: 0.5 Pa to 1 Pa
Deposition rate: 0.45 μm/min
Length of the target: 200 mm
Exterior diameter of the target: 15 mm
Voltage on the target: −700 V to −1000 V
Voltage anode: about 60 V
Current anode: 8 A to 20 A
Current on target: to 1 A
Voltage on the glowing cathode: 15 V to 25 V
Current on the glowing cathode 120 A to 150 A
Power glowing cathode: 2 kW to 3 kW
Temperature of the glowing cathode: about 2000° C.
The layer had the final composition CuSn8.
A coat thickness of the layer of 8 μm was produced.
The micrograph of the layer shows no structural texture in axial direction of the tube.

### 2. Exemplary Embodiment

The first exemplary embodiment was repeated using a target 16 of AlBi15Mo1 produced through powder metallurgy.

The following parameters were set:
Pressure: 0.66 Pa to 1 Pa
Deposition rate: 0.7 μm/min
Length of the target: 200 mm
Exterior diameter of the target: 15 mm
Voltage on the target: −1000 V to −1500 V
Voltage anode: about 60 V
Current anode: 16 A to 20 A
Current on target: up to 1 A
Voltage on the glowing cathode: 15 V to 25 V
Current on the glowing cathode 120 A to 150 A
Power glowing cathode: 2 kW to 3 kW
Temperature of the hot cathode: about 2000° C.
The layer had the final composition AlBi15Mo1.
A coat thickness of the layer of 6 to 20 μm was produced.

The samples produced after both exemplary embodiments required no post-processing anymore and could be used immediately.

The exemplary embodiments show possible variants of embodiment of the plain bearing element 13 and are not intended to limit the scope of the invention to these illustrated variants of embodiments provided herein but that there are also various combinations among the variants of the embodiments themselves and variations regarding the present invention should be executed by a person skilled in the art.

For the sake of good order, finally, it should be pointed out that, in order to provide a clearer understanding of the structure of the bearing element 1, it and its constituent parts are illustrated to a certain extent out of scale and/or on an enlarged scale and/or on a reduced scale.

### LIST OF REFERENCE NUMERALS

1 Plain bearing element
2 Surface
3 Cavity
4 Support element
5 Surface
6 Sliding layer
7 Inner diameter
8 Length
9 Bearing element body
10 Circumference
11 Apparatus
12 Housing
13 Treatment chamber
14 Bottom
15 Hood
16 Target
17 Electrode
18 Cover surface
19 Holding device
20 Bar
21 Contacting/Coupling/Connection
22 Lateral wall
23 Cavity
24 Lateral wall
25 Insulating element
26 Electrode
27 Recess
28 Diameter
29 Cooling- and/or heating elements

1. Method for producing a plain bearing element (1) by coating a surface (5) of a substrate with a tribologically effective sliding layer (6) by means of cathode sputtering in a gas atmosphere and using at least one metal target (16), wherein a substrate is used, which has a cylindrical cavity (3) and the target (16) being arranged at least partially in the cavity (3) and furthermore the discharge for sputtering the target (16) is supported or maintained by means of a third electrode (26).

2. Method according to claim 1, wherein a glowing cathode is used as third electrode (26).

3. Method according to claim 1, wherein an alloy, which starts melting at a temperature of 200° C. or melts at this temperature is used as a target (16).

4. Method according to claim 1, wherein an element selected from a group comprising Al, Cu, Ag, Sn, Bi, Sb as main alloy element is used as target (16).

5. Method according to claim 1, wherein a target (16) is used having a maximum diameter selected from a range of 5 mm to 55 mm.

6. Method according to claim 1, wherein the distance between the surface of the substrate to be coated and the surface of the target is at least 5 mm.

7. Method according to claim 1, wherein before the tribologically effective layer is produced on the surface (5) of the substrate, this surface (5) is cleaned by inverse cathode sputtering by using an inert gas.

8. Method according to claim 7, wherein during the cleaning of the surface, a voltage between −300 V and −1400 V is applied to the substrate.

9. Method according to claim 1, wherein during the coating, a bias voltage, selected from a range having a lower limit of −200 V and an upper limit of −10 V, is applied to the substrate.

10. Method according to claim 1, wherein a temperature of the substrate is open loop controlled and/or closed loop controlled during the coating.

11. Metal plain bearing element (1) with a bearing element body (9) having a support element (4) with a cylindrical cavity (3) having an inner diameter (7), with a metal sliding layer (6) being disposed at the interior surface (5), wherein the inner diameter of the bearing element body is not larger than 70 mm and the sliding layer (6) is produced through cathode sputtering.

12. Plain bearing element (1) according to claim 11, wherein the bearing element body (9) in axial direction has a length (8) that is larger than the inner diameter (7).

13. Plain bearing element (1) according to claim 11, wherein the bearing element body (9) is embodied in a seamless way.

14. Plain bearing element (1) according to claim 11, wherein the sliding layer (6) is made of an alloy having a base element which forms the main ingredient and which is selected from a group comprising Al, Cu, Ag, Sn, Pb, Bi, Sb.

15. Plain bearing element (1) according to claim 11, wherein the sliding layer (6) has a structure which is free of a texture in axial direction.
